(19) United States
(12) Patent Application Publication
(10) Pub. No.: US 2024/0409360 A1
(43) Pub. Date: Dec. 12, 2024

(54) ELECTRICAL ELEVATOR CAR DEVICE

(71) Applicant: Lift Ventures, Inc., Birmingham, MI (US)

(72) Inventors: Robert J. Wurth, Birmingham, MI (US); Adam Duren, Pensacola, FL (US)

(73) Assignee: Lift Ventures, Inc., Birmingham, MI (US)

(21) Appl. No.: 18/664,840

(22) Filed: May 15, 2024

Related U.S. Application Data
(60) Provisional application No. 63/507,274, filed on Jun. 9, 2023.

(51) Int. Cl. B66B 1/34; B66B 5/00; H03M 1/12

(52) U.S. Cl. CPC B66B 1/3461; B66B 5/0025; B66B 5/0037; H03M 1/12

(57) ABSTRACT

Systems and methods receive, by an electrical device coupled to an elevator car of an elevator and via device component(s) electrically coupled to the electrical device, analog signal(s), wherein the electrical device comprises processor(s), and wherein the analog signal(s) comprise a measurement derived from one or more elevator activities. The analog signal(s) are converted, via the electrical device, into digital data and preprocessing is performed thereon via the processor(s) of the electrical device. The preprocessed data is wirelessly transmitted, via a peripheral device of the electrical device, to remote server(s) of a cloud computing environment, the preprocessed data being transmitted, at least in part, for data aggregation and to facilitate access by user(s) for elevator asset management, wherein the remote server(s) are configured to perform additional processing of the preprocessed data as part of the data aggregation.

### CROSS-REFERENCE TO RELATED APPLICATION

This application traces priority to and claims benefit of U.S. Provisional Patent Application Ser. No. 63/507,274 filed Jun. 9, 2023, entitled “ELEVATOR CAR DATA MANAGEMENT DEVICES, SYSTEMS, AND METHODS THAT FACILITATE TARGETED MAINTENANCE”, the entirety of which is expressly incorporated herein by reference.

### FIELD OF THE INVENTION

This invention relates generally to the field of data management, and more particularly embodiments of the invention relate to elevator car data management devices, systems and methods that facilitate targeted elevator maintenance.

### BACKGROUND OF THE INVENTION

The global elevator and escalator market was estimated to be valued at $79.7 billion U.S. dollars in 2021 and expected to grow to $132.08 billion U.S. dollars by 2029. Contrive Datum Insights Pvt Ltd, Elevator and Escalator Market Sales, Demand Outlook By Product, Application, Business & Region—Forecast 2023-2030, https://www.contrivedatuminsights.com/product-report/elevator-and-escalator-market-248490/?Mode=PM. According to the National Elevator Industry, in the United States people are estimated to travel more than 2.55 billion miles on elevators and escalators each year, which is more than the total miles of air and rail travel combined. National Elevator Industry, Inc., Elevator and Escalator Fact Sheet, (2020) https://nationalelevatorindustry.org/wp-content/uploads/2020/07/NEII-Fact-Sheet-2020.pdf. It is estimated that there are more than 1.03 million elevators in the United States that make approximately 20.6 billion passenger trips per year. Id.

Elevators have many moving parts, electrical components, and safety features that could potentially break down over time. Elevator maintenance is very important in order to ensure that people can rely on this mode of transportation to access level of various structures. Traditionally, maintenance inspections are regularly performed on elevators in order to provide preventative maintenance as well as corrective maintenance. However, there are many factors that can influence how frequently an elevator will break down, which can influence maintenance scheduling needs. Thus, a need exists for improved devices, systems, and methods that can improve existing maintenance scheduling processes.

### BRIEF SUMMARY

Shortcomings of the prior art are overcome and additional advantages are provided through the provision of a computing system for elevator car data management. The system includes, for instance, a memory, one or more processors in communication with the memory, and program instructions executable by the one or more processors via the memory. The program instructions are executable to, in part, receive, by an electrical device coupled to an elevator car of an elevator and via one or more device components electrically coupled to the electrical device, one or more analog signals. The electrical device includes the one or more processors and the one or more analog signals include a measurement that is derived from one or more elevator activities. The one or more analog signals are converted, via the electrical device, into digital data, and preprocessing of the digital data is performed via the one or more processors of the electrical device. Further, the preprocessed data is wirelessly transmitted, via a peripheral device of the electrical device, to one or more remote servers of a cloud-computing environment, where the preprocessed data is transmitted, at least in part, for data aggregation and to facilitate access by one or more users for elevator asset management. In addition, the one or more remote servers are configured to perform additional processing of the preprocessed data as part of the data aggregation.

Additionally, disclosed herein is a computing system for targeted elevator maintenance. The system includes, for instance, a memory, one or more processors in communication with the memory, and program instructions executable by the one or more processors via the memory. The program instructions are executable to, in part, receive, by one or more servers of a cloud-computing environment, elevator data associated with one or more elevator activities of one or more elevators. Data analytics is performed on the elevator data, the data analytics includes implementing one or more data processing algorithms to categorize the digital data using one or more models to group data points of the digital data to generate one or more data objects, the implementing including categorizing the one or more elevators based on one or more elevator attributes. Further, the data analytics also includes identifying performance metrics of a category of elevators of the one or more elevators, where the category of elevators includes a common attribute of the one or more elevator attributes used to categorize the one or more elevators. A recommended maintenance program is generated for an elevator having the common attribute, where the recommended maintenance program is based, at least in part, on the identified performance metrics of the category of elevators that include the common attribute.

Also disclosed herein is a computer-implemented method for elevator car data management. The computer-implemented method includes, in part receiving, by an electrical device coupled to an elevator car of an elevator and via one or more device components electrically coupled to the electrical device, one or more analog signals. The electrical device includes the one or more processors, and the one or more analog signals include a measurement that is derived from one or more elevator activities. Further, the method includes converting, via the electrical device, the one or more analog signals into digital data, and performing, via the one or more processors of the electrical device, preprocessing of the digital data. The preprocessed data is wirelessly transmitted, via peripheral device of the electrical device, to one or more remote servers of a cloud-computing environment, where the preprocessed data is transmitted, at least in part, for data aggregation and to facilitate access by one or more users for elevator asset management. In addition, the one or more remote servers are configured to perform additional processing of the preprocessed data as part of the data aggregation.

The features, functions, and advantages that have been described herein may be achieved independently in various embodiments of the present invention including computer-implemented methods, computer program products, and computing systems or may be combined in yet other embodiments, further details of which can be seen with reference to the following description and drawings.

### BRIEF DESCRIPTION

One or more aspects are particularly pointed out and distinctly claimed as examples in the claims at the conclusion of the specification. The foregoing as well as objects, features, and advantages of one or more aspects are apparent from the following detailed description taken in conjunction with the accompanying drawings in which:

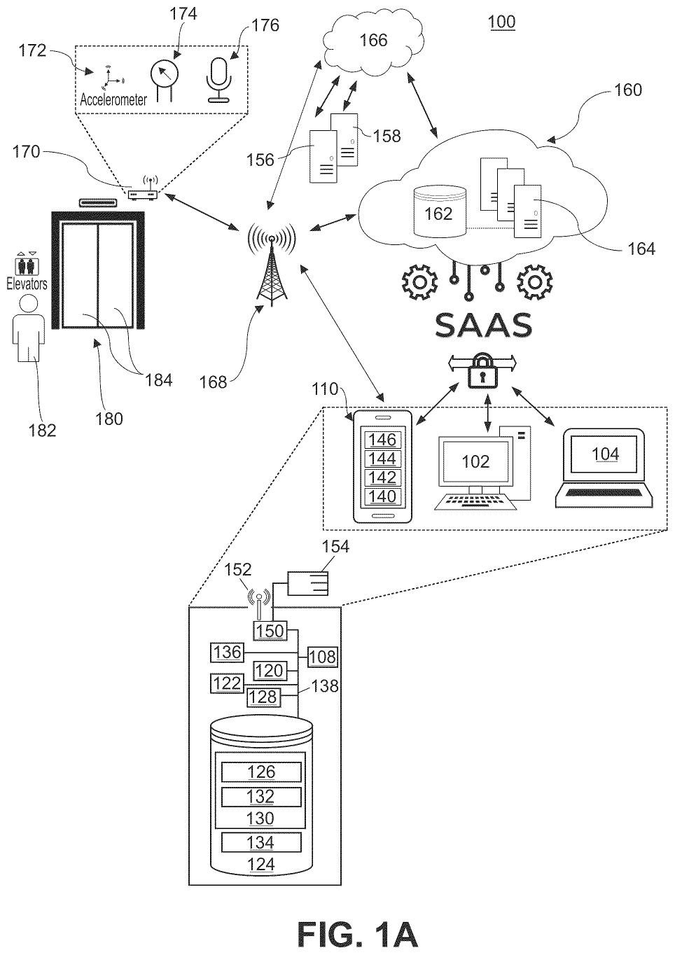

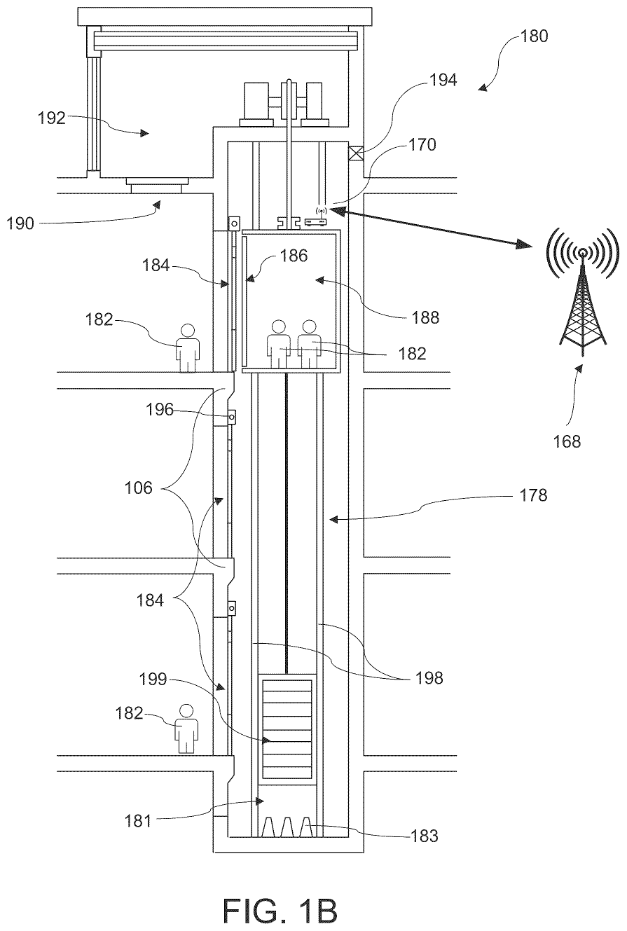

FIG. 1A illustrates an example computing environment for elevator data management, in accordance with an embodiment of the present invention;

FIG. 1B illustrates an example elevator system for use within a computing environment such as the example computing environment of FIG. 1A, in accordance with an embodiment of the present invention;

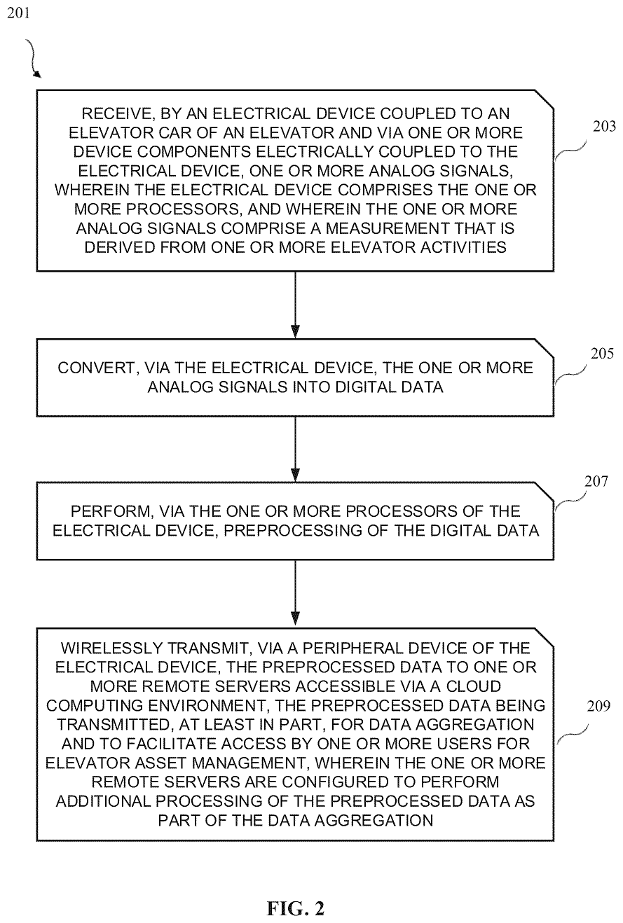

FIG. 2 depicts a block diagram of an example method for elevator car data management, in accordance with an embodiment of the present invention; and

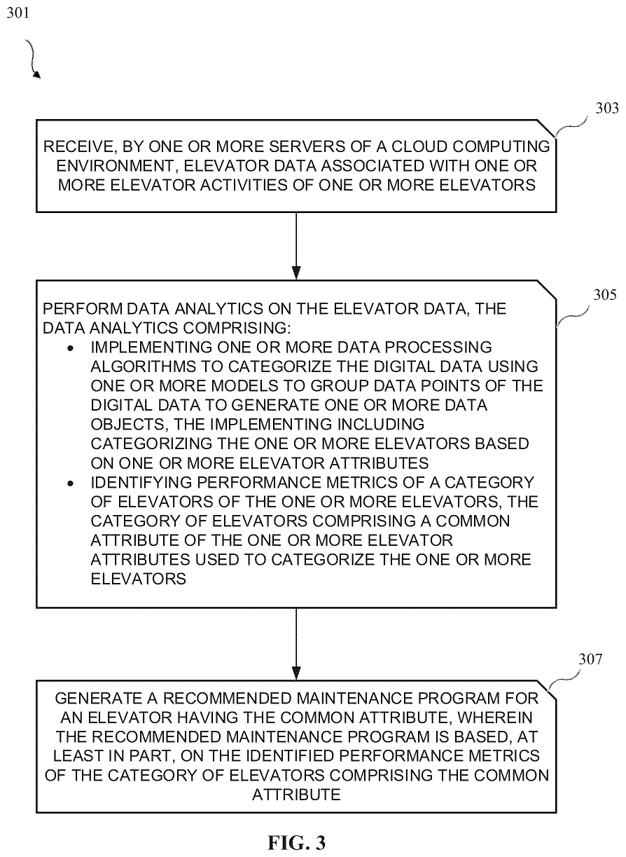

FIG. 3 depicts a block diagram of an example method for targeted elevator maintenance, in accordance with an embodiment of the present invention.

### DETAILED DESCRIPTION

Aspects of the present invention and certain features, advantages, and details thereof are explained more fully below with reference to the non-limiting examples illustrated in the accompanying drawings. Descriptions of well-known processing techniques, systems, components, etc. are omitted to not unnecessarily obscure the invention in detail. It should be understood that the detailed description and the specific examples, while indicating aspects of the invention, are given by way of illustration only, and not by way of limitation. Various substitutions, modifications, additions, and/or arrangements, within the spirit and/or scope of the underlying inventive concepts will be apparent to those skilled in the art from this disclosure. Therefore, it is to be understood that, within the scope of the included claims, the invention may be practiced other than as specifically described herein.

While certain exemplary embodiments have been described and shown in the accompanying drawings, it is to be understood that such embodiments are merely illustrative of, and not restrictive on, the broad invention, and that this invention not be limited to the specific constructions and arrangements shown and described, since various other changes, combinations, omissions, modifications and substitutions, in addition to those set forth in the above paragraphs, are possible. The figures are not necessarily drawn to scale, as some features may be exaggerated to show details of particular components. Thus, specific structural and functional details illustrated herein are not to be interpreted as limiting, but merely as a representative basis for teaching one skilled in the art to employ the present invention.

While certain exemplary embodiments have been described and shown in the accompanying drawings, it is to be understood that such embodiments are merely illustrative of, and not restrictive on, the broad invention, and that this invention not be limited to the specific constructions and arrangements shown and described, since various other changes, combinations, omissions, modifications and substitutions, in addition to those set forth in the above paragraphs, are possible. Unless described or implied as exclusive alternatives, features throughout the drawings and descriptions should be taken as cumulative, such that features expressly associated with some particular embodiments can be combined with other embodiments. Those skilled in the art will appreciate that various adaptations, modifications, and combinations of the embodiments described herein can be configured without departing from the scope and spirit of the invention. Therefore, it is to be understood that, within the scope of the included claims, the invention may be practiced other than as specifically described herein. Like numbers refer to like elements throughout. Unless defined otherwise, technical and scientific terms used herein have the same meaning as commonly understood to one of ordinary skill in the art to which the presently disclosed subject matter pertains.

Additionally, illustrative embodiments are described below using specific code, designs, architectures, protocols, layouts, schematics, or tools only as examples, and not by way of limitation. Furthermore, the illustrative embodiments are described in certain instances using particular software, tools, or data processing environments only as example for clarity of description. The illustrative embodiments can be used in conjunction with other comparable or similarly purposed structures, systems, applications, or architectures. One or more aspects of an illustrative embodiment can be implemented in hardware, software, or a combination thereof.

As understood by one skilled in the art, program code can include both software and hardware. For example, program code in certain embodiments of the present invention can include fixed function hardware, while other embodiments can utilize a software-based implementation of the functionality described. Certain embodiments combine both types of program code.

Embodiments of the present invention are described herein, with reference to flowchart illustrations and/or block diagrams of computer-implemented methods and computing systems according to embodiments of the invention. Each block of the flowchart illustrations and/or block diagrams, and combinations of blocks in the flowchart illustrations and/or block diagrams, can be implemented by computer readable program instructions that may be provided to a processor of a general purpose computer, special purpose computer, or other programmable data processing apparatus or apparatuses (the term “apparatus” includes systems and computer program products). In particular, the computer readable program instructions, which execute via the processor of the computer or other programmable data processing apparatus, create a means for implementing the functions/acts specified in the flowchart and/or block diagram block or blocks.

In one embodiment, these computer readable program instructions may also be stored in a computer-readable storage medium that can direct a computer or other programmable data processing apparatus, and/or other devices, to function in a particular manger, such that the computer readable storage medium having instructions stored therein comprises an article of manufactured including instructions which implement aspects of the actions specified in the flowchart illustrations and/or block diagrams. In particular, the computer-readable program instructions may be used to produce a computer-implemented method by executing the instructions to implement the actions specified in the flowchart illustrations and/or block diagram block or blocks.

Alternatively, in another embodiment, these computer program instructions may also be stored in a computer-readable memory that can direct a computer or other programmable data processing apparatus to function in a particular manner, such that the instructions stored in the computer readable memory produce an article of manufacture including instructions, which implement the function/act specified in the flowchart and/or block diagram block or blocks.

The computer program instructions, whether stored in the computer-readable storage medium and/or computer-readable memory may also be loaded onto a computer or other programmable data processing apparatus to cause a series of operational steps to be performed on the computer or other programmable apparatus to produce a computer implemented process such that the instructions, which execute on the computer or other programmable apparatus, provide steps for implementing the functions/acts specified in the flowchart and/or block diagram block or blocks. Alternatively, computer program implemented steps or acts may be combined with operator or human implemented steps or acts in order to carry out an embodiment of the invention.

Computer program instructions are configured to carry out operations of the present invention and may be or may incorporate assembler instructions, instruction-set-architecture (ISA) instructions, machine instructions, machine dependent instructions, microcode, firmware instructions, state-setting data, source code, and/or object code written in any combination of one or more programming languages.

An application program may be deployed by providing computer infrastructure operable to perform one or more embodiments disclosed herein by integrating computer readable code into a computing system thereby performing the computer-implemented methods disclosed herein.

Although various computing environments are described above, these are only examples that can be used to incorporate and use one or more embodiments. Many variations are possible.

In the flowchart illustrations and/or block diagrams disclosed herein, each block in the flowchart/diagrams may represent a module, segment, a specific instruction/function or portion of instructions/functions, and incorporates one or more executable instructions for implementing the specified logical function(s). Additionally, the alternative implementations and processes may also incorporate various blocks of the flowcharts and block diagrams. For instance, in some implementations the functions noted in the blocks may occur out of the order noted in the figures. For example, two blocks shown in succession may be executed substantially concurrently, or the functions of the blocks may sometimes be executed in the reverse order, depending upon the functionality involved.

The terms “coupled,” “fixed,” “attached to,” “connected to,” “communicatively coupled to,” “operatively coupled to,” “operatively connected to,” and the like should be broadly understood to refer to both: (i) direct connecting, coupling, fixing, attaching, communicatively coupling; and (ii) indirect connecting coupling, fixing, attaching, communicatively coupling via one or more intermediate components or features, unless otherwise specified herein. Elements or components may be electrically and/or mechanically coupled, for example, directly or indirectly through intervening circuitry and/or elements. “Communicatively coupled to,” communicatively connected to,” “operatively coupled to,” and “operatively connected to” can refer to physically/mechanically and/or electrically related components.

In addition, as used herein, the terms “about”, “approximately”, or “substantially” for any numerical values or ranges indicate a suitable dimensional tolerance that allows the device, part, or collection of components to function for its intended purpose as described herein.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

FIG. 1A illustrates an example computing environment 100 for elevator data management, in accordance with an embodiment of the present invention. The computing environment generally includes a cloud-computing environment, such as a distributed cloud-computing environment, that includes a private cloud (i.e., an organization-based cloud managed by either the organization or third parties and hosted on-premises or off premises), a virtual private cloud (i.e., isolated/encrypted computer resources within a public cloud), and/or a public cloud (i.e., cloud-based infrastructure available to the general public that is owned by an organization that sells cloud services). For example, the computing environment 100 depicts a distributed cloud-computing environment with one network 160 in communication with another network 166. In some embodiments, various other environments may also be included in the computing environment 100 such as, for example, a community cloud (i.e., cloud-based infrastructure shared by several organizations and manages by the organizations or third parties and hosted on-premises or off premises), a hybrid cloud (i.e., composed of two or more clouds e.g., private community, and/or public), an on-premise environment, a fog-computing environment, and edge computing environment, etc. The cloud-computing environment may include a cloud/virtual server or set of servers (e.g., servers 164) accessible on demand by one or more computing devices such as computing devices 102, 104, 110. The cloud server(s) may be configured to allow for sharing of memory 162 and processing power across the virtual servers 164.

In some embodiments, the cloud-computing environment may also be in communication with one or more on-site servers (e.g., server 156 and server 158). External or on-site servers 156, 158 represent any number of data sources. Virtual resources are considered cloud resources or virtual machines. The cloud-computing configuration may provide an infrastructure that includes a network of interconnected nodes and provides stateless, low coupling, modularity, and semantic interoperability. Such interconnected nodes may incorporate a computer system that includes one or more processors, a memory 162, and a bus that couples various system components (e.g., the memory 162) to the processor. Such virtual resources may be available for shared use among multiple distinct end-users (e.g. SaaS resource consumers) and in certain implementations, virtual resources do not necessarily correspond to one or more specific pieces of hardware, but rather to a collection of pieces of hardware operatively coupled within a cloud-computing configuration so that the resources may be shared as needed.

Example computing devices 102, 104, 110 may include a laptop, desktop computer, tablet, a smart phone, a smart watch, a smart television, and the like. The computing devices can include integrated software applications that manage device resources, generate user interfaces, accept user inputs, and facilitate communication with other devices among other functions. The integrated software applications can include an operating system, such as Linux®, UNIX®, Windows®, macOS®, iOS®, Android®, or other operating system compatible with personal computing devices. The cloud-computing environment may also be communicatively connected to various other electrical devices, including an electrical device coupled to an elevator car of an elevator 180. In some embodiments, the cloud-computing environment may provide various software service models such as software-as-a-service (SaaS).

The SaaS functionality provided by the network(s) 160, 166 enable a user to use applications running on a cloud infrastructure, where the applications are accessible via a thin client interface such as a web browser. A service provider such as an organization or business entity may manage the software application(s) hosted on the network(s) 160, 166. For the SaaS service model, the end-user is not permitted to manage or control the underlying cloud infrastructure (i.e., network, servers, operating systems, storage, or specific application capabilities that are not user-specific). In some embodiments, an independent software vendor may contract a third-party cloud provider to host the SaaS application. It is also contemplated herein that various other service models may also be utilized by or be otherwise associated with the cloud-computing environment including, for example, platform-as-a-service (PaaS) and/or infrastructure-as-a-service (IaaS). PaaS does not permit the user to manage or control the underlying cloud infrastructure, but this service may enable a user to deploy user-created or acquired applications onto the cloud infrastructure using programming languages and tools provided by the provider of the application. IaaS provides a user the permission to provision processing, storage, networks, and other computing resources as well as run arbitrary software (e.g., operating systems and applications) thereby giving the user control over operating systems, storage, deployed applications, and potentially select networking components (e.g., host firewalls).

The computing device(s) 102, 104, 110 include various computing components such as one or more processors 120, at least one memory device 122, such as random access memory (RAM), and read-only memory (ROM), that stores program instructions that are accessible and usable by the one or more processors 120. The computing device(s) 102, 104, 110 may be internet-connectable devices in order to access the cloud-based network(s) 160, 166. In particular, the computing device(s) 102, 104, 110 may communicate, such as via wireless communication device 152, across a network 160, 166 with the virtual servers 164 and/or on-site servers 156, 158. The computing device(s) 102, 104, 110 may be configured to download software application(s) from the network(s) 160, 166 after authorization credentials have been provided and access to the software application(s) has been authorized. In some embodiments, the end-users access the SaaS via a web browser. In order to access the SaaS, the end-user may provide authentication information (e.g., login information) in order to access the web browser or to download the software application(s).

The computing device(s) 102, 104, 110 may also include a storage device 124 including at least one of a non-transitory storage medium, such as a Microdrive, for long-term, intermediate-term, and short-term storage of computer-readable instructions 126 for execution by the one or more processors 120. The instructions 126 can include instructions for an operating system and various applications or programs 130, of which software application 132 is represented as a particular example of a SaaS. The storage device 124 can store various other data items 134, which can include, as non-limiting examples, cached data, user files such as those for pictures, audio and/or video recordings, files downloaded or received from other devices, and other data items preferred by the user, or required or related to any or all of the applications or programs 130. The memory device 122 is operatively coupled to the one or more processors 120. As used herein, memory includes any computer readable medium to store data, code, or other information. The memory device 122 may include volatile memory, such as volatile RAM including a cache area for the temporary storage of data. The memory device 122 may also include non-volatile memory, which can be embedded and/or may be removable. The non-volatile memory can additionally, or alternatively, include an electrically erasable programmable read-only memory (EEPROM), flash memory or the like.

According to various embodiments, the memory device 122 and storage device 124 may be combined into a single storage medium. The memory device 122 and storage device 124 can store any of a number of applications, which comprise computer-executable instructions and code executed by the one or more processors 120 to implement the functions. For example, the memory device 122 may include such applications as a conventional web browser application. These applications (e.g., integrated software applications) also typically provide a graphical user interface (GUI) on the display, and with particular reference to computing device 110, include a display 140 that allows the user to utilize or otherwise communicate with various components and systems. In particular, the GUI display screen may include features for displaying information and accepting inputs. The one or more processors 120, and other processors described herein, generally include circuitry for implementing communication and/or logic functions.

For example, the one or more processors 120 may include a digital signal processor, a microprocessor, and various analog to digital converters, digital to analog converters, and/or other support circuits. Control and signal processing functions of the computing device 102, 104, 110 are allocated between these processing devices according to their respective capabilities. The one or more processors 120 thus may also include the functionality to encode and interleave messages and data prior to modulation and transmission. The one or more processors 120 can additionally include an internal data modem. Further, the one or more processors 120 may include functionality to operate one or more software programs, which may be stored in the memory device 122, or in the storage device 124. For example, the one or more processors 120 may be capable of operating a connectivity program, such as a web browser application. The web browser application may then allow the computing device 102, 104, 110 to transmit and receive web content, such as, for example, location-based content and/or other web page content, according to a Wireless Application Protocol (WAP), Hypertext Transfer Protocol (HTTP), and/or the like.

The memory device 122 and storage device 124 can each also store any of a number of pieces of information and data that is/are used by the user device as well as applications and devices that facilitate functions of the user device, or are in communication with the user device. In particular, the memory device 122 and storage device 124 may be used to implement the functions described herein and others not expressly described. For example, the storage device may include or store data that includes user authentication information, device information, etc.

The one or more processors 120, in various examples, can operatively perform calculations, can process instructions for execution, and can manipulate information. The one or more processors 120 can execute machine-executable instructions stored in the storage device 124 and/or memory device 122 to thereby perform methods and functions, or portions thereof, as described or implied herein. In some instances, storage device 124 and/or memory device 122 may perform the methods and functions provided by one or more corresponding flow charts expressly provided or implied, as would be understood by one of ordinary skill in the art to which the subject matters of these descriptions pertain. The one or more processors 120 can be or can include, as non-limiting examples, a central processing unit (CPU), a microprocessor, a graphics processing unit (GPU), a microcontroller, an application-specific integrated circuit (ASIC), a programmable logic device (PLD), a digital signal processor (DSP), a field programmable gate array (FPGA), a state machine, a controller, gated or transistor logic, discrete physical hardware components, and combinations thereof. In some embodiments, particular portions or steps of methods and functions described herein are performed in whole or in part by way of the one or more processors 120. In some embodiments, methods and functions described herein include cloud-based computing in whole or in part such that the one or more processors 120 facilitates local operations including, as non-limiting examples, communication, data transfer, and user inputs and outputs such as receiving commands from and providing displays to the user.

The computing device 102, 104, 110 includes an input and output system 136, referring to, including, or operatively coupled with, one or more user input devices and/or one or more user output devices, which are operatively coupled to the one or more processors 120. The input and output system 136 may include input/output circuitry that may operatively convert analog signals and other signals into digital data, or may convert digital data to another type of signal. For example, the input/output circuitry may receive and convert physical contact inputs, physical movements, or auditory signals (e.g., which may be used to authenticate a user) to digital data. Once converted, the digital data may be provided to the one or more processors 120. For illustrative purposes, computing device 110 is specifically being referenced to depict a display 140, a microphone 142, a speaker 144, and a camera 146, but any computing device, including other computing device 102, 104 may also include these features/components. With specific reference to computing device 110, the input and output system 136 may also include a display 140 (e.g., a liquid crystal display (LCD), light emitting diode (LED) display, or the like), which can be, as a non-limiting example, a presence-sensitive input screen (e.g., touch screen or the like). In such cases, the display 140 serves both as an output device, by providing graphical and text indicia and presentations for viewing and as an input device, by providing virtual buttons, selectable options, a virtual keyboard, and other indicia that, when touched or via other user action, control the computing device 102, 104, 110. The user output devices can also include a speaker 144 or other audio device. The user input devices, which allow the computing device 110 to receive data and actions such as button manipulations and touches from a user. Non-limiting examples of input devices and/or output devices include, for example, a keypad, wireless or wired keyboard, touch-screen, touchpad, microphone 142, mouse, joystick, other pointer device, button, soft key, infrared sensor, a switch, a light, an LED, a buzzer, a bell, a printer and/or other input device(s). The input and output system 136 may also include a camera 146, such as a digital camera.

Inputs by one or more users can be made via voice, text or graphical indicia selections. For example, such inputs in some examples correspond to user-side actions and communications seeking services and products of the computing system, and at least some outputs in such examples correspond to data representing enterprise-side actions and communications in two-way communications. The input and output system 136 may also be configured to obtain and process various forms of authentication via an authentication system to obtain authentication information of a user.

Various authentication systems may include, according to various embodiments, a recognition system that detects biometric features or attributes of a user such as, for example fingerprint recognition systems and the like (hand print recognition systems, palm print recognition systems, etc.), iris recognition and the like used to authenticate a user based on features of the user's eyes, facial recognition systems based on facial features of the user, DNA-based authentication, or any other suitable biometric attribute or information associated with a user. Additionally or alternatively, voice biometric systems may be used to authenticate a user using speech recognition associated with a word, phrase, tone, or other voice-related features of the user. Alternate authentication systems may include one or more systems to identify a user based on a visual or temporal pattern of inputs provided by the user. For instance, the user device may display, for example, selectable options, shapes, inputs, buttons, numeric representations, etc. that must be selected in a pre-determined specified order or according to a specific pattern. Other authentication processes are also contemplated herein including, for example, email authentication, password protected authentication, device verification of saved devices, code-generated authentication, text message authentication, phone call authentication, etc. The user device may enable users to input any number or combination of authentication systems.

In various examples of authentication or authorization processes, the computing device(s) 102, 104, 110 may transmit system configuration data to the server(s) 156, 158, 164 that is used to evaluate a user or authenticate the computing device 102, 104, 110. System configuration data can include, without limitation: (i) a unique identifier for the user computing device (e.g., a media access control (MAC) address hardcoded into a communication subsystem of the user agent computing device); (ii) a MAC address for the local network of a user computing device (e.g., a router MAC address); (iii) copies of key system files that are unlikely to change between instances when a user accesses the provider system; (iv) a list of applications running or installed on the user computing device; and (v) any other data useful for evaluating users and ascertaining the subject identifiers underlying a support request or user communication.

The computing device 102, 104, 110 may also include a positioning device 108, which can be for example a global positioning system (GPS) configured to be used by a positioning system to determine a location of the computing device 102, 104, 110. For example, the positioning system device 108 may include a GPS transceiver. In some embodiments, the positioning system device 108 includes an antenna, transmitter, and receiver. For example, in one embodiment, triangulation of cellular signals may be used to identify the approximate location of the computing device 102, 104, 110.

In the illustrated example, a system intraconnect 138 (e.g., system bus), connects, for example electrically, the various described, illustrated, and implied components of the computing device 102, 104, 110. The intraconnect 138, in various non-limiting examples, can include or represent, a system bus, a high-speed interface connecting the one or more processors 120 to the memory device 122, individual electrical connections among the components, and electrical conductive traces on a motherboard common to some or all of the above-described components of the computing device 102, 104, 110. As discussed herein, the system intraconnect 138 may operatively couple various components with one another, or in other words, electrically connects those components, either directly or indirectly-by way of intermediate component(s)—with one another.

The computing device 102, 104, 110 includes a communication interface 150, by which the computing device 102, 104, 110 communicates and conducts transactions with other devices and systems (e.g., network(s) 160, 166). The communication interface 150 may include digital signal processing circuitry and may provide two-way communications and data exchanges, for example wirelessly via wireless communication device 152, and for an additional or alternative example, via wired or docked communication by mechanical electrically conductive connector 154. Communications may be conducted via various modes or protocols, of which global system for mobile communication (GSM) voice calls, SMS text, enterprise messaging service (EMS), multimedia messaging service (MMS) messaging, time division multiple access (TDMA), code division multiple access (CDMA), personal digital cellular (PDC), wideband CDMA (WCDMA), CDMA2000, and general packet radio service (GPRS), are all non-limiting and non-exclusive examples. Thus, communications can be conducted, for example, via the wireless communication device 152, which can be or include a radio-frequency transceiver, a Bluetooth device, Wi-Fi device, a Near-field communication device, and other transceivers. In addition, GPS may be included for navigation and location-related data exchanges, ingoing and/or outgoing. Communications may also or alternatively be conducted via the connector 154 for wired connections such by USB, Ethernet, and other physically connected modes of data transfer. The one or more processors 120 is configured to use the communication interface 150 as, for example, a network interface to communicate with one or more other devices on a network. In this regard, the communication interface 150 utilizes the wireless communication device 152 as an antenna operatively coupled to a transmitter and a receiver (together a “transceiver”) included with the communication interface 150. The one or more processors 120 is configured to provide signals to and receive signals from the transmitter and receiver, respectively. The signals may include signaling information in accordance with the air interface standard of the applicable cellular system of a wireless telephone network. In this regard, the computing device 102, 104, 110 may be configured to operate with one or more air interface standards, communication protocols, modulation types, and access types.

The computing device 102, 104, 110 may be configured to operate in accordance with any of a number of first, second, third, fourth, fifth-generation communication protocols and/or the like. For example, the computing device 102, 104, 110 may be configured to operate in accordance with second-generation (2G) wireless communication protocols IS-136 (TDMA), GSM, and/or IS-95 (CDMA), or with third-generation (3G) wireless communication protocols, such as Universal Mobile Telecommunications System (UMTS), CDMA2000, WCDMA and/or time division-synchronous CDMA (TD-SCDMA), with fourth-generation (4G) wireless communication protocols such as Long-Term Evolution (LTE), fifth-generation (5G) wireless communication protocols, Bluetooth Low Energy (BLE) communication protocols such as Bluetooth 5.0, ultra-wideband (UWB) communication protocols, and/or the like. The computing device 102, 104, 110 may also be configured to operate in accordance with non-cellular communication mechanisms, such as via a wireless local area network (WLAN) or other communication/data networks.

The computing device 102, 104, 110 further includes a power source 128, such as a battery, for powering various circuits and other devices that are used to operate and perform functions of the computing device 102, 104, 110.

Computing environment 100 represents at least one example of a possible implementation, where alternatives, additions, and modifications are possible for performing some or all of the described methods, operations and functions. Although shown as two networks 160, 166, in some embodiments, one or more cloud-based systems/networks, servers, memory, etc. may utilized. In some implementations, the functions of one or more systems, servers, or illustrated components may be provided by a single system or server. In some embodiments, the functions of one illustrated system or server may be provided by multiple systems, servers, or computing devices, including those physically located at a central facility, those logically local, and those located as remote with respect to each other.

The networks 160, 166 can offer any number or type of services and products accessible via any number of computing devices (e.g., computing devices 102, 104, 110). The memory (e.g., memory 162) used by the networks (e.g., networks 160, 166) may be configured to store data collected by an electrical device (e.g., electrical device 170). In general, the electrical device 170 is configured to collect data (e.g., sensor data) and communicate that data to the networks 160, 166. This collected data may be communicated to the networks 160, 166, according to one embodiment, via a cellular network 168. The memory 162 may include a non-transitory storage medium and may store digital data in a collection of storage resources (e.g., pools) such as file handles and objects (e.g., data structures, variables, functions, methods, etc.). The objects may include a value that can be referenced by identifier(s). The memory 162 may provide long-term, intermediate-term, and short-term storage of computer-readable instructions for execution. For example, the instructions can instruct an operating system and various applications or programs of various computing devices (e.g., computing devices 102, 104, 110).

The server(s) 156, 158, 164, used by the networks 160, 166 may include physical, (e.g. electrical computing devices), virtual, and/or a mix of physical and virtual servers. The server(s) 156, 158, 164 may enable users to process workloads and store large volumes of information and may be accessible on demand via an application programming interface (API). In order to provide SaaS functionality, an end-use software application may be accessible via the computing devices 102, 104, 110 (e.g., via a browser or downloadable application) that enables users of the computing devices 102, 104, 110 to access resources hosted by the networks 160, 166. The server(s) 156, 158, 164 may include metadata that includes information associated with configuration and deployment of the end-user software application, information associated with the server(s) 156, 158, 164 (e.g., hardware/software), and information associated with the SaaS infrastructure. For example, the metadata may include information related to an on-demand application, such as a customer relationship management application (CRM), an on-demand enterprise resource planning (ERP) application, and the like. In some implementations, the server(s) 156, 158, 164 and SaaS functionality may be made available to the computing devices 102, 104, 110 on a per-user subscription fee basis or on a data usage, subscription fee basis. In some embodiments, user account data, user group data, and affiliated data with specific accounts of the end-user(s) may be stored to a database or memory (e.g., memory 162). Part of the server(s) 156, 158, 164 may be private and have restricted access so that end-user(s) may only access specific information via the SaaS functionality. In another aspect, the SaaS functionality may incorporate a communication means (e.g., electronic mail communication, SMS text, and/or other messaging or alert process) in order to alert an end user, via computing devices 102, 104, 110, to a particular issue related to an elevator (e.g., such as elevator 180). In some examples, the cloud-computing environment includes a communication interface, by which the server(s) 156, 158, 164 communicate and provide information with computing devices 102, 104, 110. The communication interface may include digital signal processing circuitry and may provide two-way communication and data exchanges.

The communication interface may also be used to communicate with the electrical device 170 and provide two-way communication and data exchange with the electrical device 170.

The server(s) 156, 158, 164, used by the networks 160, 166 may include processing devices that are used to perform the methods, or portions thereof, described herein. In one example, the server(s) may include processors that automatically process data obtained, via a cellular network about an elevator (e.g., such as elevator 180), and may incorporate or otherwise include an input/output system that includes input/output devices. A system intraconnect may electrically connect various components of the networks 160, 166 such as by way of one or more intermediate components. Example system intraconnect components may include a system bus, a high-speed interface coupled to processing device(s), server(s) 156, 158, 164, memory 162, input/output devices, etc. and may include, in some examples, a motherboard common to some or all of the above-described components. Digital signal processing circuitry may also be included and may facilitate wireless communication (e.g., via cellular network 168) with the electrical device 170 and/or the computing devices 102, 104, 110. Communications may be conducted via various modes or protocols, of which GSM voice calls, SMS, EMS, MMS messaging, TDMA, CDMA, PDC, WCDMA, CDMA2000, and GPRS, are all non-limiting and non-exclusive examples. A wireless device can be or include, according to non-limiting examples, a radio-frequency transceiver, a Bluetooth device, a Wi-Fi device, a near-field communication device, and/or other transceivers. In other examples, communication between devices (e.g., between computing devices 102, 104, 110 and/or server(s) 156, 158, 164 may occur via a wired connection such as by an Ethernet connection or other physically connected modes of data transfer.

The server(s) 156, 158, 164 may include processors configured to operatively perform calculations, process instructions for execution, manipulate data/information perform data processing, perform data aggregation, data interpretation, data sorting, perform various algorithms, etc. The processors of the server(s) 156, 158, 164 may include a central processing unit (CPU), a microprocessor, a graphics processing unit (GPU), a microcontroller, an application specific integrated circuit (ASIC), a programmable logic device (PLD), a digital signal processor (DSP), a field programmable gate array (FPGA), a state machine, a controller, gated or transistor logic, discrete physical hardware components, and combinations thereof. Further, the server(s) 156, 158, 164 may be adapted to execute an operating system, such as Linux®, UNIX®, Windows®, macOS®, iOS®, Android®, or other operating systems known or used in personal computer systems, central computing systems, cellular communication, or other systems.

The networks 160, 166 may provide wireless or wired communication among components and devices of the computing environment 100, including the electrical device 170, computing devices 102, 104, 110, server(s) 156, 158, 164 and other non-illustrated devices local or remote to those illustrated. The network(s) 160, 166 are depicted as two networks for illustration purposes and convenience, but may include more or less networks without departing from the scope of these descriptions. In some implementations, the networks 160, 166 may include a secured network and may be implemented through one or more secure connections over the Internet. The networks 160, 166 can include wired and wireless links, including as non-limiting examples 802.11a/b/g/n/ac, 802.20, WiMAX, LTE, and/or any other wireless link. The networks 160, 166 may include any internal or external network(s), sub-network(s), virtual private network(s), and/or combinations thereof of any configuration operable to implement communications, data transmission, data processing, etc. between various electrical and computer devices and/or components within and beyond the illustrated computing environment 100. The networks 160, 166 may be configured to communicate Internet Protocol (IP) packets, data packets, audio data, video data, and/or other information between network addresses, devices, and components. The networks 160, 166 may include one or more local area networks (LANs), radio access networks (RANs), metropolitan area networks (MANs), wide area networks (WANs), personal area networks (PANs), WLANs, campus area network (CAN), metropolitan area network (MAN), storage-area network (SAN), all or a portion of the internet and/or any other communication system or systems at one or more locations.

The cloud-computing environment provided by the networks 160, 166 may support any number of data sources, users, end-users, consumers, customers, business entities, government entities, and/or groups of any size, which are all within the scope of the description. In some implementations the server(s) 156, 158, 164 may be configured to manually generate data or obtain data from the electrical device 170. Additionally, or alternatively, data may also be obtained from a third-party source such as, for example, a remote database. Data obtained from the electrical device 170 and/or other sources may be stored to the memory 162 and or other storage resources (e.g., any cloud-storage resource or remote server/database resource). In one example, data received from the electrical device 170 may be stored to a relational database that maintains the data in a manner that permits the content of such data to be associated with certain information. For instance, the relational database may indicate elevator models, elevator age, elevator characteristics, geographic location, business entity information, history data, a unique elevator number/identifier, maintenance information, installation information, etc. Storing the data to the relational database may facilitate expedient sorting and processing of the data such that an end-user may retrieve content data that is informative and may provide interpretable information that can be used to monitor and assess elevator information.

Often, elevator data is automatically derived from the elevator 180, but in some instances, the elevator data is manually input into the cloud-based system. In standard practice, an elevator maintenance or service call may be initiated based on a landlord, property owner, or business manually requesting a service. In other examples, elevator maintenance technicians may perform routine maintenance periodically on the elevator 180 according to a maintenance schedule. The disclosed systems and methods provide advantages over these standard practices and provide automated data transmission and collection and can help inform maintenance technicians as to the conditions of the elevator 180 and can directly provide a recommended maintenance schedule or maintenance plan for the elevator 180 in a manner that is data-driven. Advantageously, the disclosed systems and methods improve efficiency and resource utilization of elevator data maintenance companies. Further, the disclosed systems and methods can inform contract drafting for maintenance contracts in order to provide end-users with an appropriate maintenance plan that is tailored to the needs of the elevator 180.

In some embodiments, elevator data may be used to monitor, record, and assess information about an elevator 180. The elevator data may include elevator performance data that is derived from the electrical device 170 about the elevator 180 (e.g., sensor data derived from one or more sensors) and/or maintenance data related to maintenance activities. In some embodiments, the elevator data may also include elevator data derived from a control panel of the elevator 180 itself. Such elevator data may include metadata or other forms of data related to (a) maintenance data representing the date and time a service call or maintenance service was performed, (b) subject data (e.g., subject/topic data) characterizing certain maintenance functions performed or other purposes for performing a service call or maintenance service (e.g., replace bearings, align motor drive, re-grooving sheaves, etc.), (c) weighted data representing a weight or importance given to certain maintenance or service call (e.g., emergency situation), (d) elevator identifier data identifying the specific elevator, elevator location, elevator type, etc., (e) maintenance technician data indicating the technician that performed the maintenance service, (f) elevator location entity information such as contact information of the business located in the building, contact information of the landlord, etc., (g) maintenance servicer data (e.g., the entity with which there is a maintenance contract to service the elevator), (h) resolution data indicating whether a particular technical issue was resolved or not, and/or (i) other types of data that can be helpful for future maintenance or service interactions with specific elevators.

In some embodiments, an end-user database of the cloud-computing environment may comprise database records that correspond to individual customers, or end users. The end-user database records may store a variety of end-user data, including, without limitation: (i) a user identifier; (ii) user contact data, including a mailing address or a geographic region where the user resides (e.g., a zip code, city, state); (iii) user source data, such as user telephone number data, user device IP Address data, an email address, or a social media account name; (iv) user demographic data; (v) one or more product identifiers that indicate the elevator(s) currently serviced, maintained, or owned by the end-user; (vi) maintenance data that includes data and information relating to maintenance functions, such as service calls, dates when an elevator was serviced, etc.; (vii) average resource utilization data indicating the average number of maintenance calls performed for certain elevators over a given time period; (viii) user online activity data indicating end-user attempts to log into the SaaS application to access user accounts or other activities; and/or (ix) elevator configuration data, as described herein.

In some examples, end-user data/information may be provided or uploaded to the SaaS application manually by the end-user. In other embodiments, the end-user data may be automatically captured when a user performs a function via the SaaS application.

Various analytical tools (e.g., algorithmic applications) may be used to aggregate, associate, interpret, and/or otherwise leverage elevator data and/or end-user data. It is also contemplated that in some implementations, artificial intelligence (AI) and/or machine-learning programs may be associated with or conducted by processor(s), memory device(s) and/or storage devices of the computing environment. It should be appreciated that in such embodiments AI algorithm or program may be incorporated within the existing system architecture or be configured as a standalone modular component, controller, or the like communicatively coupled to the system. An Al program and/or machine learning program may generally be configured to perform methods and functions as described or implied herein. Machine-learning programs may be configured to implement various algorithmic processes and learning approaches including, for example, decision tree learning, association rule learning, artificial neural networks, recurrent artificial neural networks, long short term memory networks, inductive logic programming, support vector machines, clustering, Bayesian networks, reinforcement learning, representation learning, similarity and metric learning, sparse dictionary learning, genetic algorithms, k-nearest neighbor (KNN), and the like.

Example algorithms may include one or more regression algorithms configured to output a numerical value given an input. Further, the machine learning may include one or more pattern recognition algorithms, e.g., a module, subroutine or the like capable of translating text or string characters or data. In some embodiments, modules may be configured to perform matrix multiplication logic in order to implement various processes or to optimize data interpretation.

According to some embodiments, the algorithms may be trained or programmed to perform different interpretations based on how much data is collected. For instance, if as more data is collected, it becomes apparent that there is a certain pattern for a particular elevator model where it begins to experience certain technical failures after a certain number of uses, the algorithms may be trained or programmed to identify relational patterns and identify commonalities that could inform of a preferred maintenance schedule. Example algorithmic programming may include, for example, supervised learning, (e.g., decision tree learning, support vector machines, similarity and metric learning, etc.), unsupervised learning, (e.g., association rule learning, clustering, etc.), reinforcement learning, semi-supervised learning, self-supervised learning, multi-instance learning, inductive learning, deductive inference, transductive learning, sparse dictionary learning and the like. Example clustering algorithms used in unsupervised learning may include, for example, k-means clustering, density based special clustering of applications with noise (DBSCAN), mean shift clustering, expectation maximization (EM) clustering using Gaussian mixture models (GMM), agglomerative hierarchical clustering, or the like. According to one embodiment, clustering of data may be performed using a cluster model to group data points based on certain similarities using unlabeled data. Example cluster models may include, for example, connectivity models, centroid models, distribution models, density models, group models, graph based models, neural models and the like.

Algorithmic supervised learning software systems are trained using content data that is well-labeled or “tagged.” During training, the supervised software systems learn the best mapping function between a known data input and expected known output (i.e., labeled or tagged content data). Supervised learning software then uses the best approximating mapping learned during training to analyze unforeseen input data (never seen before) to accurately predict the corresponding output. Supervised learning software systems often require extensive and iterative optimization cycles to adjust the input-output mapping until they converge to an expected and well-accepted level of performance, such as an acceptable threshold error rate between a calculated probability and a desired threshold probability. Supervised learning software systems implement techniques that include, without limitation, Latent Semantic Analysis (“LSA”), Probabilistic Latent Semantic Analysis (“PLSA”), Latent Dirichlet Allocation (“LDA”), and more recent Bidirectional Encoder Representations from Transformers (“BERT”). Latent Semantic Analysis software processing techniques process a corporate of content data files to ascertain statistical patterns, which give insights into the maintenance processes. Unsupervised learning software systems can perform training operations on unlabeled data and less requirement for time and expertise from trained data scientists. Unsupervised learning software systems can be designed with integrated intelligence and automation to automatically discover information, structure, and patterns from content data. Unsupervised learning software systems can be implemented with clustering software techniques that include, without limitation, K-means clustering, Mean-Shift clustering, Density-based clustering, Spectral clustering, Principal Component Analysis, and the like. The content driver software service utilizes one or more supervised or unsupervised software processing techniques to perform a subject classification analysis on the elevator data. In some embodiments, predictive functionality may also be incorporated into the disclosed elevator systems.

In some embodiments, the algorithms that are trained or programmed to identify relational patterns and identify commonalities that could inform of a preferred maintenance schedule are based on machine learning algorithms that incorporate natural language processing. In particular, natural language processing may derive meaning from written or spoken text and may include speech recognition, sentiment analysis, and text summarization. For instance, in some embodiments, a mechanic or office administrator may provide verbal and/or textual inputs and natural language processing is performed thereon to interpret the inputs. In some embodiments, the algorithms may incorporate large language models (LLMs) that are trained on large amounts of data (e.g., text data) to generate human-like responses to natural language inquiries. Advantageously, LLMs may be accessed or otherwise used as part of or in conjunction with the system described herein by maintenance technicians, mechanics, office administrators, etc. to inquire about the conditions of the elevator 180 in order to obtain a recommended maintenance schedule or maintenance plan for the elevator 180. For instance, an artificial intelligence chatbot may access the elevator data stored to one or more remote servers of a cloud computing environment that are related to a specific elevator, a type of elevator, a manufacturer of elevator, etc. and use that elevator data to generate a recommended maintenance schedule or maintenance plan. Various other implementations of natural language processing, LLMs, and chatbot-based functionalities are also contemplated herein.

As disclosed herein, a data-driven maintenance approach is disclosed that better utilizes maintenance resources and provide additional efficiencies by providing for tailored maintenance of elevators. Elevator data that may be useful in influencing elevator maintenance scheduling is related to frequency of elevator use. For example, a hospital or high-rise tower may have frequent elevator use that may require more frequent elevator maintenance than a two-story exercise gym. The hospital or high-rise tower may require frequent elevator maintenance (e.g., daily, weekly, bi-weekly, monthly) rather than the elevator at the exercise gym (e.g., where quarterly maintenance may be sufficient). Thus, the maintenance contracts that landlords, property owners, and businesses enter into with elevator maintenance companies should be better tailored to the needs of the business rather than defaulting to standard maintenance terms that are not informed by data. Elevator maintenance companies and elevator consultants that provide maintenance management programs would benefit from the improvements described herein.

In order to collect elevator data, most standard elevators do not include a built-in mechanism to track and monitor elevator use or to distribute elevator data to an external system, like computing environment 100, for processing and interpretation. Thus, disclosed herein is an electrical device 170 that is configured to be coupled to an elevator car and collect data about the elevator 180. As referred to herein, an elevator (such as elevator 180) may be any electromechanical device used to load or transport people (such as passenger 182) or things to different floors or levels. Although not limited to this particular limitation, often an elevator may include a car/cab/platform/etc. housed within a shaft that provides vertical transport. Example elevators may include hydraulic, geared/gearless traction, machine-room-less, belt-driven, screw-driven, and vacuum elevators. However, the systems and methods described herein may be equally applicable to passenger elevators, service elevators, goods elevators, etc.

The electrical device 170 may be battery powered, according to one embodiment, and coupled to the interior of the elevator car. In another embodiment, the electrical device 170 may be hardwired and electrically connected to an electrical outlet/receptacle (e.g., a 120 V outlet) that is coupled to the roof of the elevator car in accordance with code requirements. For instance, the electrical device 170 may be positioned on top of the roof of the elevator car within the elevator shaft. In some embodiments, the electrical device 170 may be positioned within the elevator car and be electrically coupled to an electrical outlet/receptacle of the elevator car. In some embodiments, the electrical device 170 may be in communication with and/or electrically connected to the control system of the elevator itself. Various other implementations and/or combinations are also contemplated herein.

The electrical device 170 various electrical components including, for instance, one or more sensor(s). The electrical device 170 may be configured to receive one or more analog signals from the one or more sensor(s). In example embodiments, the electrical components of the electrical device 170 may include an accelerometer 172, an altimeter 174 (e.g., a barometric pressure sensor), and/or a microphone 176 that detect specific elevator activities. The one or more analog signals may include measurement data that is derived from one or more elevator activities, and the electrical device 170 may be able to convert the one or more analog signals into digital data. Once converted to digital data, one or more processors of the electrical device may perform preprocessing of the digital data. The preprocessing may be performed via a compute module of a microcontroller.

The microcontroller of the electrical device 170 may include or consist of a small computing device on a single integrated circuit chip that includes one or more computer processing units (processor cores) along with a memory and programmable input/output peripherals. The memory of the microcontroller may include ferroelectric RAM that stores program instructions executable by the computer processing units. The microcontroller may include one or more general purpose input/output (GPIO) pins configurable to input or output information such as read sensors or analog signals. The microcontroller includes an analog-to-digital converter that is used to convert the analog data into a format the computer processing units can recognize. The microcontroller may be configured to provide real-time responses to elevator events/activities. For instance, the microcontroller may include a universal asynchronous receiver/transmitter block to receive and/or transmit data. A peripheral interface may be used to communicate with external device(s) such as, for example, a gateway device. An internet-of-things (IoT) gateway or other peripheral device may be used to connect the microcontroller to the Internet via a cellular or Wi-Fi connective technology and may serve as the connection point for a cloud platform with the microcontroller and sensor(s) of the electrical device 170. Thus, the IoT gateway may serve as a bridging connection and may facilitate software update downloads to the electrical device 170 or other data inputs and may also facilitate data transmission across the cellular network 168 to the cloud-computing environment of computing environment 100. In some embodiments, the peripheral device includes a gateway (e.g., an on-premises server) and preprocessed data is initially transmitted through the gateway, which serves as an intermediary device, prior the transmitting preprocessed data to one or more remote servers. Advantageously, in embodiments in which the electrical device 170 is battery powered, using the gateway may decrease the wireless transmit power and thereby prolong the battery life of the battery of the electrical device 170.

The sensor(s) (e.g., the accelerometer 172, altimeter 174, and/or a microphone 176) may be configured to detect power loss, idle drift, acceleration, speed, jerk, vibration, position, etc. For instance, the altimeter 174 may be configured to detect position, the accelerometer 172 may be configured to detect acceleration, and the microphone 176 may be configured detect decibels that might indicate a maintenance issue if the car is traveling loudly (e.g., due to being out of alignment). The digital data derived from the analog signal(s) may include time series data (indicating how long did the elevator accelerate vs. decelerate), and changes in position over time, number of elevator trips, acceleration data (e.g., related to takeoff and landing), jerk data (e.g., related to takeoff and landing) which may indicate whether an elevator is out of adjustment and shakes/jerks when it reaches a destination floor. Vibration data may also be used to interpret shaking of the elevator car at a constant travel speed, decibel data may also indicate, for example, how loud certain elevator components are at constant speed, speed data indicating maximum speed, etc. Landing position data may also be collected that indicates what floor the elevator goes to or where the elevator has been located in order to analyze elevator traffic patterns.

Other features or aspects detected by the electrical device 170 may include floor-to-floor time, trips per floor, delay, wait time/dwell time, trip distribution per car (e.g., in a bank/set of elevators how is the distribution of trips spread out among the elevators with the bank/set of elevators). Additionally, the electrical device may also be able to detect a likely shutdown event, where the elevator stops working based on the absence of certain measurements detected by the sensor(s).

In one particular example, if the elevator 180 includes a hydraulic system and the elevator car slips so that when the elevator car lands at a desired floor, if there is a leak in the hydraulic system the elevator car may not accelerate as quickly or may drop below the elevator landing and then self-correct. This data can be detected based on the accelerator data and from this, the cloud-computing environment may detect an anomaly and provide an alert/warning via the SaaS functionality to a maintenance technician or maintenance service provider that there is an anomaly being detected related to the elevator.

Another possible sensor of the electrical device 170 may include a temperature sensor since temperature (particularly in the machine room of an elevator system) could potentially influence elevator function. A water-leak detection sensor could also be incorporated into the pit of the elevator shaft to provide an early warning of water pooling in the elevator shaft that would also require elevator maintenance. In some embodiments, the electrical device 170 could also include a sensor to monitor door movement and/or a sensor to monitor environmental conditions (e.g. such as environmental conditions in the machine room of the elevator system).

In some embodiments, it is also contemplated that the IoT gateway of the electrical device may receive inputs (e.g., queries) to determine whether data is not being automatically transmitted due to a problem or based on non-use. For example, data may indicate that there is an anomaly in elevator use of an elevator within a bank/set of elevators. An input may be transmitted to two different electrical devices of respective elevators within a bank/set of elevators to determine if one elevator in the set is operating at expected levels and the other elevator that is not moving. If the result of the query is that one elevator in the set is operating as expected with multiple trips and the other elevator is not moving as frequently as expected (or not moving at all), then that would indicate there may be a problem. Alternatively, if the result of the query is that neither elevator within the bank/set of elevators is operating as frequently as expected, then this might indicate a functional problem with the elevator and may just be due to changing traffic patterns (e.g., all employees in the building have the day off for a company event) and is not being used as much as usual.

In some embodiments, the data collected by the electrical device 170 is collected and sent as data packets if the electrical device 170 is not able to get a good cellular signal at all points within the elevator shaft. For instance, the elevator 180 may not have good reception when positioned at a basement level/floor within the shaft, but when the elevator rises to the 10th floor of the building, the cellular signal might be stronger and the data packets may then be transmitted via the cellular network at that time. Similarly, data may be sent via a Wi-Fi system or other wireless means of communication in locations where cellular signal is unavailable.

FIG. 1B illustrates an example elevator 180 (i.e., an elevator system) for use within a computing environment such as the example computing environment 100 of FIG. 1A, in accordance with an embodiment of the present invention. The elevator 180 may be in communication via a cellular network 168 with the cloud-computing environment discussed above. The elevator 180 may include a machine room 192 that stores elevator equipment (e.g., a pump unit, a controller, electrical systems, etc.) that enable the elevator to operate. The elevator system may also include a smoke vent 194, a shaft 178 within which an elevator car 188 vertically travels. The elevator car 188 may include one or more elevator car doors 186 and may be coupled to the electrical device 170 described above. The elevator car 188 may be configured to transport a load, such as a person/passenger 182. The elevator 180 may also include an access door to access the machine room, a sliding door gear 196, a landing 106, and landing door 184. The elevator 180 may also include a counter weight 199 and guide(s) 198. The elevator shaft 178 may also include a pit 181 that includes buffer(s) 183.

FIG. 2 depicts a block diagram of an example method 201 for elevator car data management, in accordance with an embodiment of the present invention. At a high level, one SaaS application/feature disclosed herein includes asset management functionalities that pools a variety of data sources from multiple electrical devices coupled to elevator cars and stores that data within a computing environment, such as computing environment 100 described herein. In a specific use-case, the method 201 includes receiving, at block 203, by an electrical device coupled to an elevator car of an elevator and via one or more device components (e.g., sensor(s)) electrically coupled to the electrical device, one or more analog signals, where the electrical device includes one or more processors (e.g., as part of a microcontroller) and the one or more analog signals include a measurement that is derived from one or more elevator activities.

According to one embodiment, the one or more device components is selected from the group consisting of an accelerometer, an altimeter, and a microphone. Further, according to various embodiments, the measurement that is derived from one or more elevator activities is selected from the group consisting of an acceleration measurement, a position measurement, a vibration measurement, a decibel measurement, and a velocity measurement. The electrical device may include a microcontroller that includes one or more processors. At block 205, the one or more analog signals may be converted, via the electrical device, into digital data, and at block 207 preprocessing of the digital data may be performed via the one or more processors of the electrical device. According to one embodiment, digital data are selected from the group consisting of time series data, acceleration data, position data, vibration data, decibel data, and velocity data.

At block 209, the preprocessed data may be wirelessly transmitted, via a peripheral device of the electrical device, to one or more remote servers accessible via a cloud-computing environment. The preprocessed data may be transmitted, at least in part, for data aggregation and to facilitate access by one or more users for elevator asset management. According to one embodiment, the preprocessed data is wirelessly transmitted via a cellular network to the one or more remote servers. In addition, the one or more remote servers are configured to perform additional processing of the preprocessed data as part of the data aggregation. According to one embodiment, the additional processing comprises implementing one or more data processing algorithms to categorize the digital data using one or more models to group data points of the digital data to generate one or more data objects. According to one embodiment, the electrical device comprises the memory and wherein the digital data and preprocessed data are transitorily stored to the memory prior to transmitting the preprocessed data to the one or more remote servers.

As described herein, the preprocessed data may be related to and/or include elevator data that indicates what maintenance has or has not been performed on the elevator, and based on the preprocessed data being wirelessly transmitted, the data aggregation may include maintenance records and elevator data that is made available to the one or more users via SaaS. From the data that is available via SaaS, the user(s) may utilize the information to generate maintenance contracts for the elevators.

According to various embodiments, the method 201 may also receive, by the electrical device, data inputs from a server of the one or more remote servers of the cloud-computing environment, and the method 201 may also include processing, via the one or more processors, the data inputs. According to one embodiment, the data inputs include updates to functionality of the electrical device, and the data inputs may be received in response to one or more detected usage anomalies.

According to one embodiment, the preprocessed data may be automatically transmitted at successive intervals (e.g., periodically, according to a schedule, based on Internet connectivity, etc.) over a period of time. In some implementations, in addition to hosting and performing data aggregation of the preprocessed data, the one or more remote servers further host software accessible to the one or more users via a software-as-a-service software distribution model.

FIG. 3 depicts a block diagram of an example method 301 for targeted elevator maintenance, in accordance with an embodiment of the present invention. In general, another SaaS application/feature disclosed herein may be utilized to facilitate targeted maintenance of an elevator that is data-driven. In particular, the targeted maintenance application/feature provides a maintenance algorithm for an elevator based on the elevator data and automatically incorporating the maintenance algorithm into a maintenance contract.

At block 303, one or more servers of a cloud-computing environment receive elevator data associated with one or more elevator activities of one or more elevators. Such elevator data may include elevator performance data that is derived from the elevator (e.g., sensor data derived from one or more sensors) and/or elevator maintenance data related to maintenance activities. In some embodiments, the maintenance data may include information captured by an elevator company's maintenance logs or tickets, which may be used an inputs for a targeted maintenance algorithm. In various implementations, maintenance data may be obtained from a mechanic, from an office administrator, and/or from various other individuals associated with a maintenance company or that contribute to maintenance service. At block 305, data analytics is performed on the elevator data, where the data analytics includes implementing one or more data processing algorithms to categorize the digital data using one or more models to group data points of the digital data to generate one or more data objects. Implementation of the data processing algorithm(s) includes categorizing the one or more elevators based on one or more elevator attributes. Further, the data analytics includes identifying performance metrics of a category of elevators of the one or more elevators, where the category of elevators includes a common attribute of the one or more elevator attributes used to categorize the one or more elevators.

At block 307, a recommended maintenance program is generated for the elevator having the common attribute, where the recommended maintenance program is based, at least in part, on the identified performance metrics of the category of elevators comprising the common attribute.

In some embodiments, one or more sections of a maintenance contract (e.g., a legal contract) may be automatically populated with contract terms derived from the recommended maintenance program. Further, the recommended maintenance program is accessible, via the one or more servers, to one or more users via a software-as-a-service software distribution model. Further, the elevator data associated with one or more elevator activities may be selected from the group consisting of time series data, acceleration data, position data, vibration data, decibel data, and velocity data.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to explain the principles of one or more aspects of the invention and the practical application thereof, and to enable others of ordinary skill in the art to understand one or more aspects of the invention for various embodiments with various modifications as are suited to the particular use contemplated.

It is to be noted that various terms used herein such as “Linux®”, “Windows®”, “macOS®”, “iOS®”, “Android®”, and the like may be subject to trademark rights in various jurisdictions throughout the world and are used here only in reference to the products or services properly denominated by the marks to the extent that such trademark rights may exist.

What is claimed is:

1. A computing system for an electrical elevator car device, the computing system comprising:
an electrical device coupled to an elevator car of an elevator, the electrical device comprising:
a memory;
one or more processors in communication with the memory; and
program instructions stored by the memory and executable by the one or more processors to:
receive, by the electrical device via one or more device components electrically coupled to the electrical device, one or more analog signals, and wherein the one or more analog signals comprise a measurement that is derived from one or more elevator activities;
convert, via the electrical device, the one or more analog signals into digital data;
perform, via the one or more processors of the electrical device, preprocessing of the digital data; and
wirelessly transmit, via a peripheral device of the electrical device, the preprocessed data to one or more remote servers of a cloud computing environment, the preprocessed data being transmitted, at least in part, for data aggregation and to facilitate access by one or more users for elevator asset management, wherein the one or more remote servers are configured to perform additional processing of the preprocessed data as part of the data aggregation.

2. The computing system for elevator car data management of claim 1, wherein the additional processing comprises implementing one or more data processing algorithms to categorize the digital data using one or more models to group data points of the digital data to generate one or more data objects.

3. The computing system for elevator car data management of claim 1, wherein the preprocessed data is wirelessly transmitted via a cellular network to the one or more remote servers.

4. The computing system for elevator car data management of claim 1, wherein the one or more device components is selected from the group consisting of an accelerometer, an altimeter, and a microphone.

5. The computing system for elevator car data management of claim 1, wherein the measurement that is derived from one or more elevator activities is selected from the group consisting of an acceleration measurement, a position measurement, a vibration measurement, a decibel measurement, and a velocity measurement.

6. The computing system for elevator car data management of claim 1, wherein the digital data are selected from the group consisting of time series data, acceleration data, position data, vibration data, decibel data, and velocity data.

7. The computing system for elevator car data management of claim 1, wherein the electrical device comprises a microcontroller, and wherein the microcontroller comprises the one or more processors.

8. The computing system for elevator car data management of claim 1, wherein the electrical device comprises the memory and wherein the digital data and preprocessed data are transitorily stored to the memory prior to transmitting the preprocessed data to the one or more remote servers.

9. The computing system for elevator car data management of claim 1, wherein the program instructions are further executable to:
receive, by the electrical device, data inputs from a server of the one or more remote servers of the cloud computing environment; and
process, via the one or more processors, the data inputs.

10. The computing system for elevator car data management of claim 9, wherein the data inputs comprise updates to functionality of the electrical device.

11. The computing system for elevator car data management of claim 9, wherein the data inputs are received in response to one or more detected usage anomalies.

12. The computing system for elevator car data management of claim 1, wherein the preprocessed data is automatically transmitted at successive intervals over a period of time.

13. The computing system for elevator car data management of claim 1, wherein, in addition to hosting and performing data aggregation of the preprocessed data, the one or more remote servers further host software accessible to the one or more users via a software-as-a-service software distribution model.

14. The computing system for elevator car data management of claim 1, wherein the peripheral device comprises a gateway and the transmitting of the preprocessed data comprises initially transmitting the preprocessed data through the gateway prior the transmitting to the one or more remote servers.

15. A computing system for targeted elevator maintenance, the computing system comprising:
a cloud computing environment comprising one or more servers, the one or more servers comprising one or more processors and a memory; and
program instructions stored by the memory and executable by the one or more processors to:
receive, by one or more servers of a cloud computing environment, elevator data associated with one or more elevator activities of one or more elevators;
perform data analytics on the elevator data, the data analytics comprising:
implementing one or more data processing algorithms to categorize the elevator data using one or more models to group data points of the elevator data to generate one or more data objects, the implementing including categorizing the one or more elevators based on one or more elevator attributes; and
identifying performance metrics of a category of elevators of the one or more elevators, the category of elevators comprising a common attribute of the one or more elevator attributes used to categorize the one or more elevators; and
generate a recommended maintenance program for an elevator having the common attribute, wherein the recommended maintenance program is based, at least in part, on the identified performance metrics of the category of elevators comprising the common attribute.

16. The computing system for targeted elevator maintenance of claim 15, wherein the program instructions are further executable by the one or more processors to automatically populate one or more sections of a maintenance contract with contract terms derived from the recommended maintenance program.

17. The computing system for targeted elevator maintenance of claim 15, wherein the recommended maintenance program is accessible, via the one or more servers, to one or more users via a software-as-a-service software distribution model.

18. A computer-implemented method for elevator car data management, the computer-implemented method comprising:
receiving, by an electrical device coupled to an elevator car of an elevator and via one or more device components electrically coupled to the electrical device, one or more analog signals, wherein the electrical device comprises one or more processors, and wherein the one or more analog signals comprise a measurement that is derived from one or more elevator activities;
converting, via the electrical device, the one or more analog signals into digital data;
performing, via the one or more processors of the electrical device, preprocessing of the digital data; and
wirelessly transmitting, via a peripheral device of the electrical device, the preprocessed data to one or more remote servers of a cloud computing environment, the preprocessed data being transmitted, at least in part, for data aggregation and to facilitate access by one or more users for elevator asset management, wherein the one or more remote servers are configured to perform additional processing of the preprocessed data as part of the data aggregation.

19. The computer-implemented method of claim 18, wherein the additional processing comprises implementing one or more data processing algorithms to categorize the digital data using one or more models to group data points of the digital data to generate one or more data objects.

20. The computer-implemented method of claim 18, wherein in addition to hosting and performing data aggregation of the preprocessed data, the one or more remote servers further host software accessible to the one or more users via a software-as-a-service software distribution model.
